(19) United States
(12) Patent Application Publication
(10) Pub. No.: US 2024/0279897 A1
(43) Pub. Date: Aug. 22, 2024

(54) HATCH ASSEMBLY

(71) Applicant: GB Design Limited, Auckland (NZ)

(72) Inventor: Greig Reid Brebner, Warkworth (NZ)

(73) Assignee: GB Design Limited, Auckland (NZ)

(21) Appl. No.: 18/569,802

(22) PCT Filed: Jun. 15, 2022
(86) PCT No.: PCT/IB2022/055520

§ 371 Date: Dec. 13, 2023

(30) Foreign Application Priority Data
Jun. 16, 2021 (AU) 2021901799

(51) Int. Cl. E02D 29/14

(52) U.S. Cl. CPC E02D 29/1427; E02D 29/1463

(57) ABSTRACT

A hatch assembly comprising a frame presenting a frame opening, a hatch for opening and closing the frame opening, a plurality of pivot assemblies. At least two pairs of the pivot assemblies each provide a hatch pivot axis at or adjacent a side of the hatch, an engagement mechanism engagement mechanism configured to releasably engage the pivot assemblies to couple the hatch to the frame, and an actuation mechanism. The engagement mechanism comprises a plurality of pins, each pin movable between an extended position to engage a said pivot assembly and a retracted position to disengage from the pivot assembly. The pins are oriented so that longitudinal axes of the pins in each pair of pins converge enabling the hatch to remain coupled to the frame when the hatch is pivoted between the closed position and an open position.

### STATEMENT OF CORRESPONDING APPLICATIONS

This application is based on Australian patent application 2021901799, the entire contents of which are incorporated herein by reference.

### FIELD OF INVENTION

The invention relates to a hatch assembly with a pivoting hatch configurable to pivot from more than one side.

### BACKGROUND TO THE INVENTION

A hatch is provided over a hatch opening and is movable between a closed position and an open position to provide access through the hatch opening. It is common for hatches to be pivotally mounted to a frame presenting the hatch opening to pivot between open and closed positions.

Typically, a hatch is pivotally coupled at one side of the hatch and frame. For example, for a vertically arranged hatch, e.g. in a vertical wall, a hatch may be pivotally mounted to pivot open at a left or right side, or an upper or lower side. When installing a hatch, a decision must be made as to for which side the hatch should pivot.

In other configurations a hatch may be releasable from a frame to provide access through the hatch opening provided through the frame.

It may be desirable to provide a hatch assembly that is configurable so that the hatch may be closed and pivoted open from a closed position by pivoting about two or more sides, or all sides of the hatch. It may be further desirable to provide a hatch that can additionally be configured to be removed from a frame.

A configurable hatch assembly is preferably uncomplicated and easily configured between different available configurations.

### OBJECT OF THE INVENTION

It is an object of the invention to provide a hatch assembly that overcomes one or more of the above-mentioned disadvantages, or that at least provides the public with a useful choice.

### SUMMARY OF THE INVENTION

According to a first aspect of the invention, there is provided a hatch assembly comprising:
a frame presenting a frame opening;
a hatch for opening and closing the frame opening;
a plurality of pivot assemblies, wherein at least two pairs of the pivot assemblies each provide a hatch pivot axis at or adjacent a side of the hatch, an engagement mechanism configured to releasably engage the pivot assemblies to couple the hatch to the frame;
wherein the engagement mechanism comprises a plurality of pins, each pin movable between an extended position to engage a said pivot assembly and a retracted position to disengage from the pivot assembly; and
an actuation mechanism configured to move the pins between the extended and retracted positions, to selectively couple the hatch to the frame by:
   (i) all of the pivot assemblies engaged by all of the pins to couple the hatch to the frame in a closed position, and
   (ii) any said pair of pivot assemblies engaged by a corresponding pair of the pins to selectively pivotally-couple the hatch to the frame to pivot on the hatch pivot axis at or adjacent any of at least two sides of the hatch, and
wherein the pins are oriented so that longitudinal axes of the pins in each pair of pins converge enabling the hatch to remain coupled to the frame when the hatch is pivoted between the closed position and an open position.

In some embodiments, the actuation mechanism is further configured to move all of the pins to the retracted position to uncouple the hatch from the frame to optionally remove the hatch from the frame.

In some embodiments, pairs of the pivot assemblies each provide a hatch pivot axis at or adjacent a side of the hatch so that the plurality of pivot assemblies provides a hatch pivot axis at or adjacent each side of the frame. The actuation mechanism is configured to selectively couple the hatch to the frame by any said pair of pivot assemblies engaged by a corresponding pair of the pins to selectively pivotally-couple the hatch to the frame to pivot on the hatch pivot axis at or adjacent any side of the hatch.

In some embodiments, one or more pivot assemblies comprises at least two pivot axes. The one or more pivot assemblies with at least two pivot axes is shared between two adjacent hatch pivot axes for two adjacent sides of the hatch and frame. The pivot assembly is utilised in two adjacent pairs of pivot assemblies.

In some embodiments, each pivot assembly comprises at least two pivot axes, wherein each pivot assembly is shared between two adjacent hatch pivot axes for two adjacent sides of the hatch and frame. Each pivot assembly is utilised in two adjacent pairs of pivot assemblies.

In some embodiments, each pivot assembly is associated with a corner of the hatch and frame.

In some embodiments, pairs of adjacent pivot assemblies each provide a hatch pivot axis, and wherein the actuation mechanism is configured to selectively pivotally-couple the hatch to the frame by any said pair of adjacent pivot assemblies engaged by a corresponding pair of adjacent pins.

In some embodiments, the number of hatch pivot axes is equal to the number of pivot assemblies.

In some embodiments, the angle between the longitudinal axis of each pin and the corresponding hatch pivot axis is between 20 and 70 degrees, or 30 and 60 degrees. Preferably the angle between the longitudinal axis of each pin and the corresponding hatch pivot axis is half of a corner angle of the hatch and frame. Preferably the angles between the longitudinal axes of the pins and corresponding hatch pivot axes are the same for each pin.

In some embodiments, the actuation mechanism provides a plurality of closed positions to selectively couple the hatch to the frame in the closed position. In some embodiments, in each closed position a handle of the actuation mechanism is aligned towards a corner region of the hatch.

In some embodiments, the actuation mechanism provides a plurality of open positions, in each open position the hatch pivotally coupled to the frame to pivot on a said hatch pivot axis. In some embodiments, in each open position a handle of the actuation mechanism is oriented away from the respective hatch pivot axis.

In some embodiments, the actuation mechanism comprises a cam to move the pins between the extended and retracted positions. Each pin is coupled to the cam by a cam follower and a connecting element extending between the cam follower and the pin. The cam comprises at least one cam surface to act on and thereby move the cam-followers between a radially inward position and a radially outward position to move the pins between the retracted and extended positions.

In some embodiments, the connecting element is a strut.

In some embodiments, the cam captures the cam followers in a radial direction so that the cam followers are moved between the radially inwards position and the radially outwards position by rotation of the cam.

In some embodiments the cam comprises a first cam comprising at least one first cam surface for moving the pins between the retracted and extended positions to couple the hatch to the frame in the closed position and pivotally couple the hatch to the frame by a pair of pivot assemblies, and a second cam comprising at least one second cam surface moveable relative to the at least one first cam surface to move the pair of pins engaged with a corresponding pair of pivot assemblies from the extend position to the retracted position to uncouple the hatch from the frame to optionally remove the hatch from the frame.

In some embodiments, the second cam is moveable relative to the first cam to move the pair of pins engaged with a corresponding pair of pivot assemblies from the extended position to the retracted position.

In some embodiments, the at least one first cam surface and the at least one second cam surface are aligned to move the pins between the retracted and extended positions to couple the hatch to the frame in the closed position and pivotally couple the hatch to the frame by a pair of pivot assemblies. The second cam is moved relative to the first cam to move the at least one second cam surface out of alignment with the at least one first cam surface to move the pair of pins engaged with a corresponding pair of pivot assemblies from the extend position to the retracted position to uncouple the hatch from the frame to optionally remove the hatch from the frame

In some embodiments, rotation of the first cam moves the pins between the retracted and extended positions to couple the hatch to the frame in the closed position and pivotally couple the hatch to the frame by a pair of pivot assemblies, and movement of the second cam lateral to a rotational axis of the first cam moves the pair of pins engaged with a corresponding pair of pivot assemblies from the extended position to the retracted position to uncouple the hatch from the frame to optionally remove the hatch from the frame.

In some embodiments, the first and second cams are rotationally fixed together, wherein rotation of the first and second cams together moves the pins between the retracted and extended positions to couple the hatch to the frame in the closed position and pivotally couple the hatch to the frame by a pair of pivot assemblies.

In some embodiments, the first cam captures the cam followers in a radial direction so that the cam followers are moved between the radially inwards position and the radially outwards position by rotation of the first cam to move the pins between the retracted and extended positions to couple the hatch to the frame in the closed position and pivotally couple the hatch to the frame by a pair of pivot assemblies, and
and the second cam captures the cam followers in a radial direction so that the cam followers are moved between the radially inwards position and the radially outwards position by movement of the second cam relative to the first cam to move the pair of pins engaged with a corresponding pair of pivot assemblies from the extend position to the retracted position to uncouple the hatch from the frame to optionally remove the hatch from the frame.

In some embodiments, the first cam comprises a first track to capture the cam followers and the second cam comprises a second track to capture the cam followers, and the first track and the second track are aligned to move the pins between the retracted and extended positions to couple the hatch to the frame in the closed position and pivotally couple the hatch to the frame by a pair of pivot assemblies. The second cam is moved relative to the first cam to move the second track out of alignment with the first track to move the pair of pins engaged with a corresponding pair of pivot assemblies from the extend position to the retracted position to uncouple the hatch from the frame to optionally remove the hatch from the frame.

In some embodiments, each pin is coupled to the actuation mechanism by a connecting element received in a channel or passageway. In some embodiments, the channels or passageways are curved so that the connecting elements are curved when received in the channels or passageways so that the pins extend at a preferred angle between the longitudinal axis of each pin and the corresponding hatch pivot axis. In some embodiments, the connecting elements are curved when received in the channels or passageways so that ends of the connecting elements opposite to the pins extend from the actuating mechanism at a preferred angle.

In some embodiments, the connecting element is a strut. In some embodiments, the channels or passageways are curved, and the struts are elastically deformed to be received in the curved channels or passageways and elastically deform as the struts are moved along the curved channels or passageways to move the pins between the retracted and extended positions so that the pins extend at a preferred angle between the longitudinal axis of each pin and the corresponding hatch pivot axis.

Each pivot assembly comprises a first part and a second part pivotally coupled together. For example, in preferred embodiments, each pivot assembly comprises a ball and socket joint. The first part is fixed to or formed with the frame or hatch. The second part is releasably engaged by a said pin to couple the hatch and the frame together by the pivot assembly. The second part remains coupled to the first part when the hatch and frame are uncoupled from the pivot assembly by disengaging the pin from the second part.

Each said pivot assembly comprises an aperture to receive a corresponding pin when in the extended position.

In some embodiments, the ball comprises a slot between the aperture and a side of the ball so that the aperture is open to a side of the ball to allow for the pin to clip out of the ball when the hatch is moved from the closed position to beyond the open position to avoid breaking the pivot assembly, the hatch or the frame. The ball may comprise a cavity extending through the ball between the aperture and the outside of the ball to provide resiliency to the ball to allow the pin to clip out of the ball.

The aperture in the ball may be offset from a central axis of the ball to allow the hatch to pivot from the closed position to the open position by more than 90 degrees.

Each pivot assembly is mounted to the hatch or the frame and the engagement mechanism is mounted to the other one of the hatch or frame. In some embodiments, each pivot assembly is mounted to the frame and the engagement mechanism is mounted to the hatch. The hatch or frame is coupled to the pivot assemblies only by the pins engaging the pivot assemblies. Therefore, the hatch is coupled to the pivot assemblies only by the pins engaging the pivot assemblies.

In some embodiments, each pivot assembly comprises a spring to return the pivot assembly to a closed orientation when the pin is retracted from the pivot assembly. One or more pivot assemblies may comprise two pivot axes and two springs, each spring associated with a respective pivot axis. For example, the pivot assembly comprises a ball and socket, a pair of keys attached to the ball, each key configured to rotate relative to the ball about a respective pivot axis, and the socket comprising a pair of corresponding keyways to receive the keys to limit movement of the ball to pivot about the two pivot axes, and each spring acting between the ball and a respective key to return the ball to the closed orientation. In some embodiments, a first key is configured to rotate relative to the ball about a first pivot axis and is received in a corresponding first keyway in the socket to prevent the first key rotating about the first pivot axis relative to the socket and allow the ball to pivot about a second pivot axis, and a second key is configured to rotate relative to the ball about the second pivot axis and is received in a corresponding second keyway in the socket to prevent the second key rotating about the second pivot axis relative to the socket and allow the ball to pivot about the first pivot axis.

In some embodiments, the hatch or pivot assembly may include a key member and the other one of the hatch and pivot assembly has a corresponding keyway to be engaged by the key. For example, the hatch comprises a key associated with each pivot assembly and each pivot assembly comprises a corresponding keyway, e.g. the ball comprises the keyway. The key is received in the keyway when the hatch is coupled to the corresponding pivot assembly. The key and keyway are configured so that the key engages and disengages the keyway by pivoting of the hatch about the hatch pivot axis at an opposite side of the hatch. The key and keyway are shaped to resist or restrict the hatch from pulling away from the (pair of) connected pivot assemblies when the hatch is opened. By example, the key and keyway are dovetail shaped.

According to a second aspect of the invention, there is provided a hatch assembly comprising:
a frame presenting a frame opening;
a hatch for opening and closing the frame opening;
a plurality of pivot assemblies, wherein each pivot assembly comprises at least two pivot axes, so that adjacent pairs of the pivot assemblies each provide a hatch pivot axis at or adjacent a side of the hatch, with each pivot assembly shared between two adjacent hatch pivot axes for two adjacent sides of the hatch, the plurality of pivot assemblies providing a hatch pivot axis adjacent each side of the hatch;
an engagement mechanism configured to releasably engage the pivot assemblies to couple the hatch to the frame;
wherein the engagement mechanism comprises a plurality of pins, each pin movable between an extended position to engage a said pivot assembly and a retracted position to disengage from the pivot assembly; and
an actuation mechanism configured to move the pins between the extended and retracted positions, to selectively couple the hatch to the frame by:
   (i) all of the pivot assemblies engaged by all of the pins to couple the hatch to the frame in a closed position, and
   (ii) any said pair of pivot assemblies engaged by a corresponding pair of the pins and with the other pivot assemblies disengaged to selectively pivotally-couple the hatch to the frame to pivot on the hatch pivot axis at or adjacent any side of the hatch, and
wherein longitudinal axes of the pins in each pair of pins converge towards a centreline of the hatch, so that the hatch remains coupled to the frame when the hatch is pivoted to the open position.

The second aspect of the invention may comprise any one or more features of the hatch assembly described above in relation to the first aspect of the invention.

### Definitions

The terms ‘rectangular’ or ‘square’ or other such shapes are not intended to be limiting to mean precisely the stated geometric shape. For example, a square or rectangular hatch or opening may be generally square or rectangular but have rounded corners or one or more sides with some curvature. Furthermore, each ‘side’ of the hatch may be understood to be a side of the hatch extending between a pair of pivot assemblies on which the hatch can pivot. For example, a hatch assembly according to the present invention comprising a circular hatch and frame and three pivot assemblies providing three pairs of adjacent pivot assemblies may be understood to have three sides.

Unless the context clearly requires otherwise, throughout the description and the claims, the words “comprise”, “comprising”, and the like, are to be construed in an inclusive sense as opposed to an exclusive or exhaustive sense, that is to say, in the sense of “including, but not limited to”.

The entire disclosures of all applications, patents and publications cited above and below, if any, are herein incorporated by reference.

Reference to any prior art in this specification is not, and should not be taken as, an acknowledgement or any form of suggestion that that prior art forms part of the common general knowledge in the field of endeavour in any country in the world.

The invention may also be said broadly to consist in the parts, elements and features referred to or indicated in the specification of the application, individually or collectively, in any or all combinations of two or more of said parts, elements or features.

Further aspects of the invention, which should be considered in all its novel aspects, will become apparent to those skilled in the art upon reading of the following description which provides at least one example of a practical application of the invention.

### BRIEF DESCRIPTION OF THE DRAWINGS

One or more embodiments of the invention will be described below by way of example only, and without intending to be limiting, with reference to the following drawings, in which:

FIGS. 1A to 1D illustrate a hatch assembly according to one embodiment of the present invention. FIG. 1A shows the hatch assembly in a closed configuration. FIGS. 1B and 1C each show the hatch assembly in an open configuration in which a hatch of the assembly can pivot open and closed about a hatch pivot axis at one edge as shown. FIG. 1D shows the hatch assembly in an uncoupled or released configuration in which the hatch can be removed from a frame of the hatch assembly.

FIGS. 2A to 2D illustrate the same hatch assembly configurations as shown in FIGS. 1A to 1D but with the hatch remaining in the hatch frame and with hidden detail shown to illustrate operation of an actuation mechanism and engagement mechanism of the hatch assembly.

FIG. 3 is an enlarged view of FIG. 2A.

FIGS. 4A and 4B show the hatch assembly of FIGS. 1A to 1D and an enlarged view of a pivot assembly of the hatch assembly with the hatch engaged to the pivot assembly.

FIGS. 5A and 5B show the hatch assembly of FIGS. 1A to 1D and an enlarged view of a pivot assembly of the hatch assembly with the hatch disengaged to the pivot assembly.

FIG. 6A is an exploded view of the hatch assembly of FIGS. 1A to 1D viewed from an outside of the hatch assembly.

FIG. 6B is an exploded view of the hatch assembly of FIGS. 1A to 1D viewed from an inside of the hatch assembly.

FIGS. 7A to 7D illustrate another hatch assembly in closed, open and uncoupled configurations respectively, corresponding with the configurations shown in FIGS. 1A to 1D, and with hidden detail shown to illustrate operation of an actuation mechanism and engagement mechanism of the hatch assembly.

FIG. 8A is an exploded view of the hatch of the hatch assembly of FIGS. 7A to 7D viewed from an outside of the hatch.

FIG. 8B is an exploded view of the hatch of the hatch assembly of FIGS. 7A to 7D viewed from an inside of the hatch.

FIG. 8C is an exploded view of the frame of the hatch assembly of FIGS. 7A to 7D viewed from an outside of the frame. An inner cap of the hatch is also shown.

FIGS. 9 and 10 illustrate a ball of the pivot assembly of the hatch assembly of FIGS. 7A to 7D, where FIG. 9 is a side view and FIG. 10 is an isometric view.

FIG. 11 illustrates the hatch assembly of FIGS. 7A to 7D with the hatch in a fully open position.

FIGS. 12 and 13 illustrate the pivot assembly of the hatch assembly of FIGS. 7A to 7D.

FIG. 14 illustrates the ball of the pivot assembly of the hatch assembly of FIGS. 7A to 7D.

FIG. 15 provides a sectional view of the pivot assembly of the hatch assembly of FIGS. 7A to 7D on a section plane passing through a centre of the ball.

FIG. 16 is an exploded isometric view of the pivot assembly of FIGS. 7A to 7D viewed from below.

FIG. 17 is an exploded isometric view of the hatch assembly of FIGS. 7A to 7D viewed from above.

FIGS. 18A to 18D illustrate the same hatch assembly configurations as shown in FIGS. 1A to 1D with the hatch assembly applied to a suitcase.

FIG. 19A to 19D illustrate another hatch assembly according to another embodiment of the present invention embodied in a manhole cover.

FIG. 20 illustrates schematically another hatch assembly according to another embodiment the present invention, providing for pivoting of the hatch about two adjacent hatch pivot axes.

FIG. 21 illustrates schematically another hatch assembly according to another embodiment the present invention, providing for pivoting of the hatch about three adjacent hatch pivot axes.

FIG. 22 illustrates schematically another hatch assembly according to another embodiment the present invention, providing for pivoting of the hatch about two hatch pivot axes at opposite sides of the hatch.

FIGS. 23A and 23B illustrate the hatch assembly of Figure of FIGS. 7A to 7D but with an alternative pivot assembly, including an enlarged view of the pivot assembly in the area indicated by the circle in FIG. 23B.

### BRIEF DESCRIPTION OF PREFERRED EMBODIMENTS OF THE INVENTION

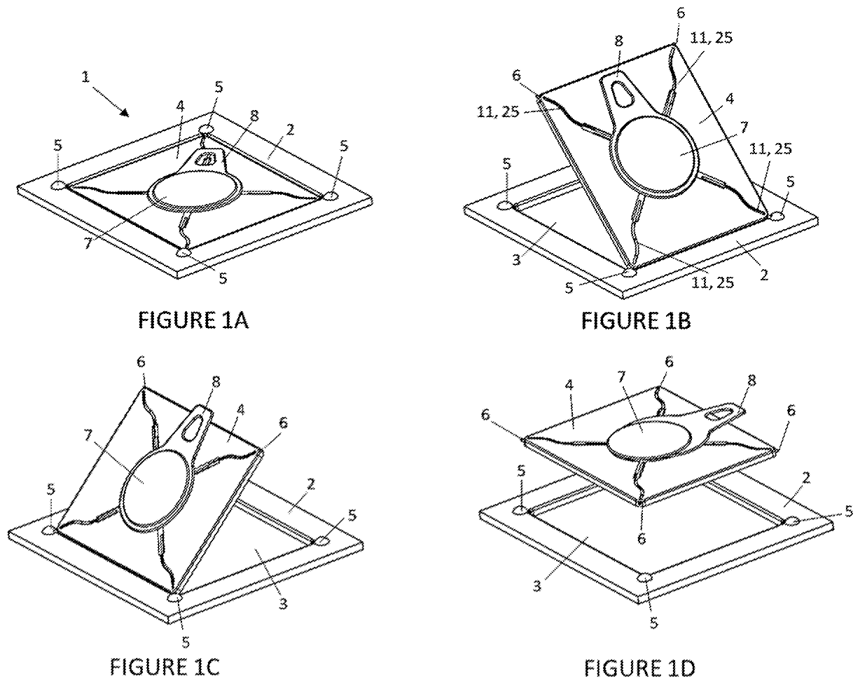

A hatch assembly according to the present invention is shown in FIGS. 1A to 1D, with the hatch illustrated in various configurations. The hatch assembly 1 comprises a frame 2 presenting an opening 3, a hatch 4 for closing the opening 3, and a plurality of pivot assemblies 5. The hatch 4 is coupled to the frame 2 via the pivot assemblies 5 to allow the hatch 4 to pivot relative to the frame 2 between a closed position to cover or close the opening 3 as shown in FIG. 1A and an open position to uncover or open the opening 3 to provide access to the opening 3 through the frame as shown in FIGS. 1B and 1C. In the illustrated embodiment, a pair of pivot assemblies is provided for each side of the hatch and frame. Each pivot assembly 5 is associated with each corner of the hatch and frame.

The hatch assembly is configured so that the hatch can pivot relative to the frame about a plurality of hatch pivot axes. Each hatch pivot axis is at or adjacent a side of the hatch or frame. In the illustrated embodiment, the hatch can open and close about a hatch pivot axis at or adjacent any one of its (four) sides. The Figures only show the hatch pivoting open about a hatch pivot axis at or adjacent two of its sides, however one will appreciate that in the illustrated embodiment the hatch may be pivoted open on a hatch pivot axis at or adjacent each of its sides. Furthermore, in a most preferred embodiment, the hatch assembly is further configured to allow the hatch to be releasably removed from the frame, as shown in FIG. 1D.

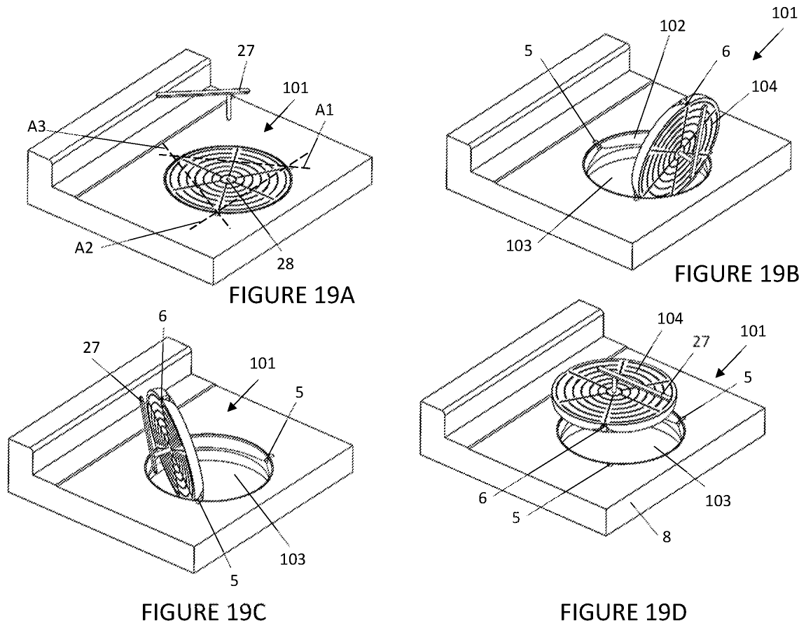

In the illustrated embodiments, the hatch has four sides, however a hatch and corresponding frame/frame opening may have three, four or more sides. Further, the invention may be incorporated in a hatch assembly comprising a circular hatch and frame, as shown in FIGS. 19A to 19D.

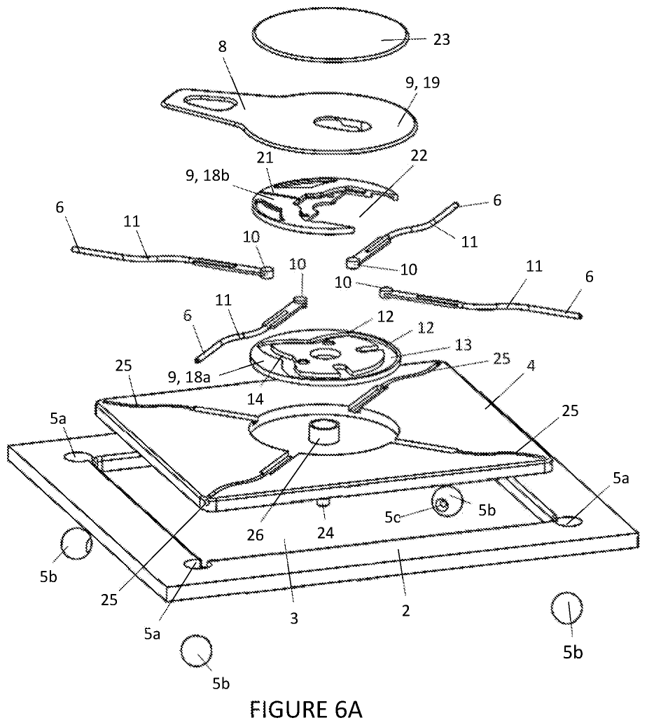

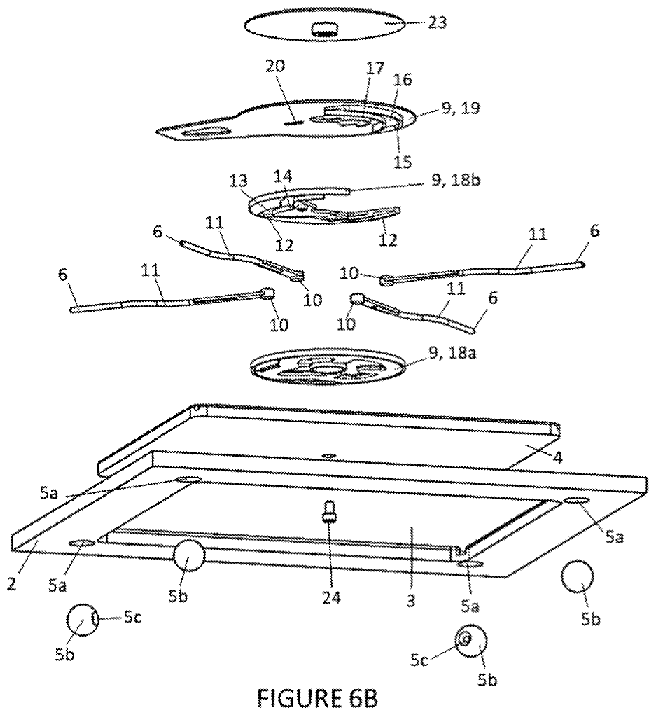

In the illustrated embodiments, each pivot assembly 5 is mounted to the frame 2. With reference to FIG. 6A, each pivot assembly 5 comprises a first part 5a fixed to or formed with the frame 2, and a second part 5b coupled to the first part 5a and adapted to pivot relative to the first part 5a (and therefore the frame). The second part 5b remains coupled to the first part 5a in normal use.

In the illustrated embodiments the pivot assembly comprises a ball and socket joint, with a socket (the first part 5a) fixed to the frame and a ball (the second part 5b) received in the socket. The ball is configured to rotate within the socket to pivot relative to the frame. Other pivot assembly arrangements may be contemplated, for example the male/female sense of the parts 5a, 5b may be reversed.

In the illustrated embodiment each pivot assembly is adapted to pivot about at least two axes. For example, each pivot assembly may be adapted to pivot about two orthogonal pivot axes. A ball and socket joint provides more than two pivot axes however in use the ball may pivot on two axes only.

The hatch assembly 1 further comprises an engagement mechanism configured to releasably engage the pivot assemblies. In the illustrated embodiments, the engagement mechanism is mounted to the hatch 4. The engagement mechanism comprises a plurality of pins 6. Each pin is configured to be moved to releasably engage a pivot assembly 5. Each pin is configured to move between an extended position to engage the pivot assembly and a retracted position to disengage from the pivot assembly. With the pin 6 in the extended position the hatch 4 is coupled to the pivot assembly 5, and with the pin 6 in the retracted position the hatch 4 is uncoupled from the pivot assembly 5.

The second part 5b of the pivot assembly 5 comprises an aperture 5c (ref to FIG. 6A) to receive a corresponding pin 6 when the pin 6 is moved to the extended position. In the extended position the pin 6 is received in the aperture 5c of the pivot assembly 5 to engage the pivot assembly and couple the hatch 4 to the pivot assembly 5. When the pin 6 is moved to the retracted position the pin 6 is removed from the aperture 5c to disengage from the pivot assembly 5 and uncouple the hatch 4 from the pivot assembly 5. The pivot assembly may comprise a biasing element (spring) to bias the pivot assembly to a closed orientation so that the aperture is in a correct alignment to receive the corresponding pin when the pin is moved from the retracted position to the extended position to engage the pivot assembly. For example, the biasing element/spring may be a rubber band acting in tension between the ball and socket to return the ball to the closed orientation when the pin is retracted from the ball.

The hatch assembly 1 further comprises an actuation mechanism 7 to move the pins 6 between the extended and retracted positions, to selectively couple the hatch to the frame in a number of different configurations. With the plurality of pins extended to engage the plurality of pivot assemblies (that is, all of the pins engaged with all of the pivot assemblies) the hatch is configured in the closed configuration as shown in FIG. 1A. With a pair of the pins 6 in the extended position to engage a corresponding pair of pivot assemblies, and with all other pins retracted to be disengaged from the other pivot assemblies, the hatch is coupled to the frame via the pair of pivot assemblies only, to configure the hatch to pivot between the closed and open position about the hatch pivot axis at or adjacent a side of the hatch and frame. With one pair of pins in the extended position and the remaining pins in the retracted position, the hatch is pivotally coupled to the frame by one pair of pivot assemblies.

In a preferred embodiment, the actuation mechanism is configured to couple the hatch to the frame by any pair of the pins and corresponding pair pivot assemblies, so that the hatch is selectively configurable to pivot open and closed on the hatch pivot axis at or adjacent any side of the hatch and frame opening.

In the illustrated embodiment, each pair of adjacent pivot assemblies in the plurality of pivot assemblies provides a hatch pivot axis. Each pivot assembly is utilised in adjacent hatch pivot axes. The number of hatch pivot axes is therefore equal to the number of pivot assemblies. By example, the hatch has four sides, four pivot assemblies and four corresponding pins. The four pivot assemblies provide a total of four pairs of pivot assemblies, each pair providing a hatch pivot axis at or adjacent a side of the hatch and frame. Pairs of adjacent pins engage the corresponding pair of adjacent pivot assemblies. The hatch is therefore configurable to pivot about a hatch pivot axis at or adjacent any one of the four sides of the hatch and frame by selectively engaging any one of the four pairs of pins with a corresponding pair of pivot assemblies.

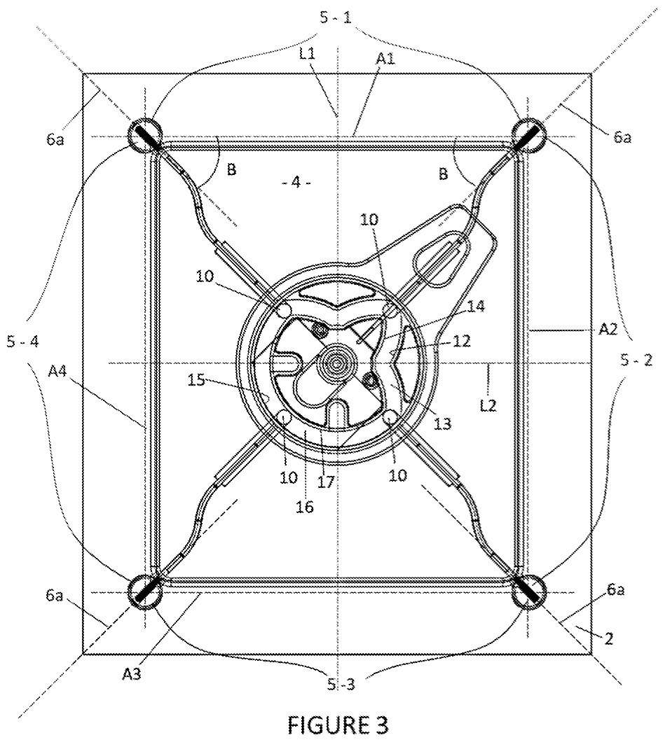

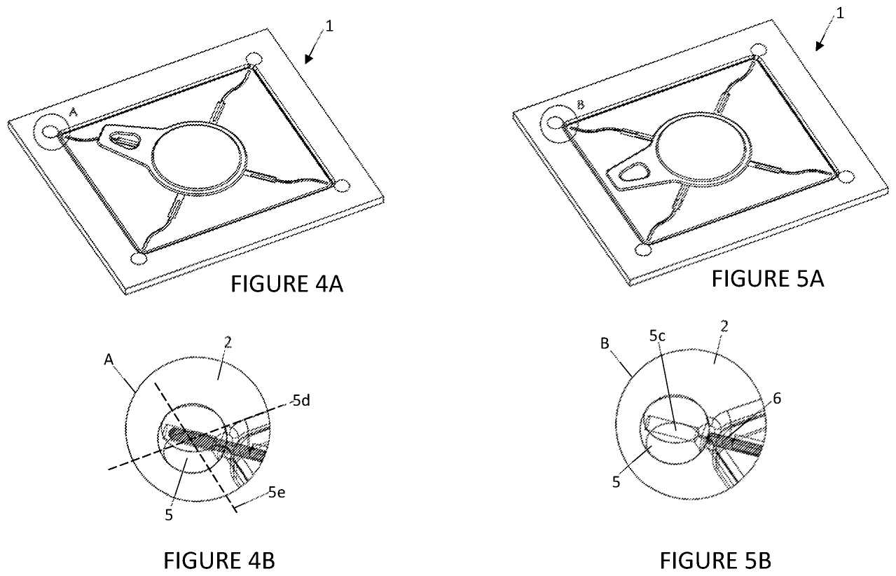

With reference to FIG. 4B, each pivot assembly provides at least two pivot axes 5d, 5e with each pivot assembly shared between two adjacent hatch pivot axes for two adjacent sides of the hatch and frame. In each pair of pivot assemblies 5, a pivot axis of one pivot assembly is aligned with a pivot axis of the other pivot assembly in the pair of pivot assemblies, to provide the hatch pivot axis for a side of the hatch and frame. The four pairs of pivot assemblies 5 with corresponding pairs of pins 6 are identified in FIG. 3 as pairs 5-1, 5-2, 5-3 and 5-4, each pair providing one of the four hatch pivot axes A1, A2, A3 and A4. However, as described above, a hatch assembly according to the present invention may have three, four or more sides with corresponding three, four or more pairs of pivot assemblies providing three, four or more hatch pivot axes.

In the illustrated embodiments the hatch is selectively coupled to the frame by any pair of adjacent pins 6 and corresponding pair of adjacent pivot assemblies 5, with each pair of adjacent pivot assemblies providing a hatch pivot axis at or adjacent a side of the hatch. However, the hatch assembly 1 may further comprise one or more additional pivot assemblies (not shown) located between one or more of the pairs of adjacent pivot assemblies that provide the hatch pivot axes. The pivot assemblies located between a pair of adjacent pivot assemblies providing a hatch pivot axis may provide a single pivot axis only. The pivot axes of the pivot assemblies on one side of the hatch and frame are aligned to provide the hatch pivot axis.

With reference to FIG. 3, each pin 6 has a longitudinal axis 6a. In accordance with the present invention, the pins are oriented so that longitudinal axes of the pins in each pair of pins converge. The pins converge in a direction from the corresponding pair of pivot assemblies towards a centre of the hatch, i.e. towards a centre region or centreline of the hatch. By way of explanation, for each pair of pins 6 coupling the hatch 4 to a corresponding pair of pivot assemblies 5 to pivot on a corresponding hatch pivot axis, the longitudinal axes 6a of the pins 6 converge towards a centreline L1, L2 of the hatch 4. For example, the longitudinal axes of the pins in pair 5-1 converge to cross centreline L1 within a perimeter of the hatch, and the longitudinal axes of the pins in pair 5-2 converge towards centreline L2 to cross centreline L2 within a perimeter of the hatch. The pins are oriented so that the longitudinal axes 6a of the pins in each pair of pins extend from the pair of pivot assemblies at opposed angles to converge. Each opposed angle extends between the pin longitudinal axis 6a and a respective hatch pivot axis, e.g. opposed angles B and hatch pivot axis A1. Each opposed angle may be half of a corner angle of the hatch, or half of the angle between the hatch pivot axes of adjacent sides of the hatch. For example, in the illustrated embodiment comprising a rectangular hatch, the angle between the longitudinal axis 6a and the hatch pivot axis is 45 degrees. Other angles are possible, however preferably the angle between the pin longitudinal axis and the hatch pivot axis is between 20 and 70 degrees, or 30 and 60 degrees. In a most preferred embodiment, the angles between the longitudinal axes of the pins and corresponding hatch pivot axes are the same for each pin.

With the longitudinal axes 6a of the pair of pins 6 converging at opposed angles to the hatch pivot axis, A1, A2, A3, A4, the hatch 4 remains attached to the pair of pivot assemblies 5 when the hatch 4 is pivoted about the hatch pivot axis from the closed position to the fully open position. With the pins engaged to the pivot assemblies converging at opposed angles to the hatch pivot axis, the hatch cannot be pulled away from the pivot assemblies when the hatch is open. No other coupling means to couple the hatch to each pivot assembly other than the pair of pins is required. The hatch 4 is coupled to the pivot assemblies 5 only by the pins 6.

The actuation mechanism 7 provides at least one position in which all of the pins 6 are moved to the extended position to engage all of the pivot assemblies 5 to couple the hatch 4 to the frame 2 in the closed position. In the illustrated embodiment, the actuation mechanism 7 provides four closed positions to move all of the pins to the extended position to couple the hatch to the frame in the closed position. FIG. 1A illustrates the actuation mechanism 7 in one of the four closed positions. In the closed position, a handle 8 of the actuation mechanism is aligned towards a corner region of the hatch. In each of the closed positions, the handle points to a corner of the hatch to indicate to a user the hatch is coupled or locked in closed.

The actuation mechanism 7 also provides an open position to couple the hatch to the frame for each pair of pivot assemblies and hatch pivot axis. Thus, in the illustrated embodiment, with four sides, the actuation mechanism provides four open positions, in each open position the hatch 4 is coupled to the frame 2 by a pair of pivot assemblies to pivot about the respective hatch pivot axis at or adjacent a side of the hatch and frame. FIGS. 1B and 1C show the actuation mechanism 7 in two of the four open positions. In each open position, the handle 8 of the actuation mechanism is oriented away from the respective hatch pivot axis, or towards an open side of the hatch and frame, indicating to a user to which side the hatch will open.

With reference to FIGS. 6A and 6B, in the illustrated embodiment, the actuation mechanism 7 includes a cam 9 to move the pins 6 between the extended and retracted positions. Each pin is coupled to the cam 9 via a cam follower 10 and a connecting element 11 extending between the cam follower 10 and the pin 6. The cam follower may be an end of the connecting element. Rotation of the cam 9 moves the cam-followers 10 and connected pins 6 to move the pins 6 between the extended and retracted positions.

The cam 9 provides a cam surface 12 to act on and thereby move the cam-followers 10. As the cam 9 is rotated the cam-followers 10 move along the cam surface 12 to move between a radially inward position and a radially outward position, to move the pins 6 between the retracted and extended positions.

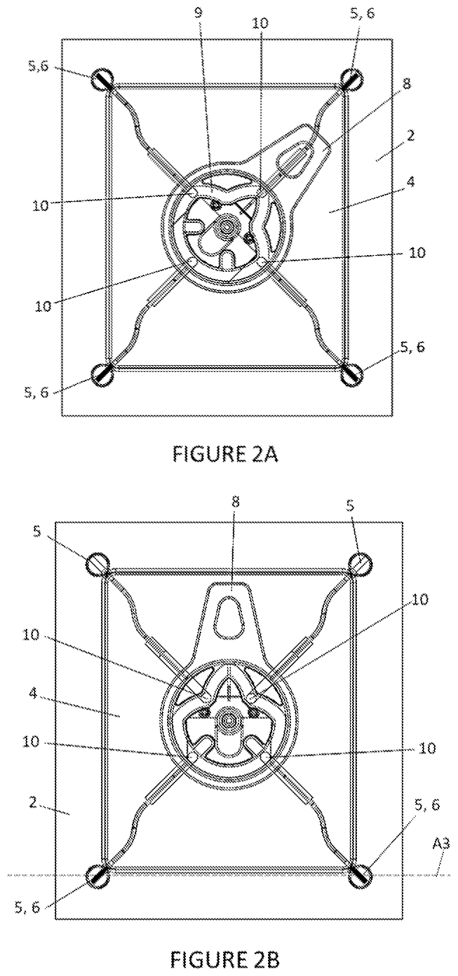

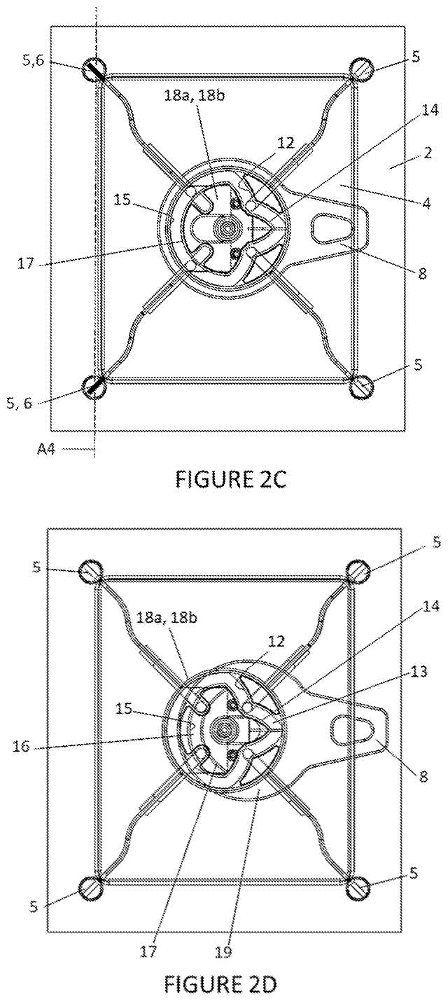

With reference to FIGS. 2A to 2D, to couple the hatch to the frame in the closed position, the cam 9 is rotated to a closed position to move the cam-followers to the radially outward position to move all of the pins to the extended positions to couple the hatch 4 to the frame 2 by all of the pivot assemblies, as shown in FIG. 2A. To pivotally couple the hatch 4 to the frame 2 by a pair of pivot assemblies 5 to pivot on the respective hatch pivot axis at or adjacent a side of the hatch, the cam 9 is rotated to an open position to move two of the cam-followers 10 to the radially outwards position with the other cam-followers 10 moved to the radially inwards position, to move one pair of the pins 6 to the extended position and the remaining pins 6 to the retracted position, as shown in FIGS. 2B and 2C.

In some embodiments, the pins 6 may be biased to the extended position by a biasing element or spring (not shown). The spring may be located at the connecting element 11, at the cam follower end of the connecting element 11 connecting the cam follower 10 to the pin 6, or at the pin or pin end of the connecting element 11. The cam surface 12 may act on the cam-followers to pull the cam followers radially inwards against the action of the biasing element, to move the pins to the retracted position, and allow the cam-followers 10 to move to the radially outward position to allow the pins 6 to move to the extended position under action of the biasing element. Alternatively, the pins may be biased to the retracted position and the cam may move the cam-followers radially outwards to move the pins to the extended positions against the action of the spring elements and allow the cam-followers to move radially inwards to move the pins to the retracted positions under action of the biasing elements.

In the illustrated embodiment, the cam 9 comprises a track 13 to capture the cam followers in a radial direction so that the cam followers are moved between the radially inwards position and the radially outwards position by rotation of the cam 9. One side 12 of the track 13 acts on the cam-followers to move the cam-followers 10 to the radially inward position, and an opposite side 14 moves the cam-followers to the radially outwards position. In such an embodiment comprising the pins 6 may not be biased by a biasing element. However, where the pins are biased outwards only the cam surface 12 may be provided. Where the pins are biased inwards, only the cam surface 14 may be provided.

In the illustrated embodiment, the actuation mechanism is also configured to move all of the pins 6 to the retracted position so that the hatch 4 can be optionally removed from the frame 2, as shown in FIGS. 1D and 2D.

With reference to FIGS. 6A and 6B, to move all of the pins 6 to the retracted position, the cam 9 comprises a first cam surface or surfaces 12, 14 for moving the cam-followers in pairs to the radially outwards position and with the other cam-followers moved to the radially inwards position, to move one pair of the pins 6 to the extended position and the remaining pins 6 to the retracted position, to pivotally couple the hatch to the frame as described above. Additionally, the cam 9 comprises a second cam surface or surfaces 15, 17 (FIG. 6B) moveable relative to the first cam surface or surfaces 12, 14 for moving the pair of the cam-followers 10 that are in the radially outwards position from the radially outwards position to the radially inwards position, so that all of the pins 6 are in the retracted position, to uncouple the hatch from the frame.

The cam 9 comprises a first cam 18a, 18b and a second cam 19. The first cam surface or surfaces 12, 14 are provided on the first cam 18a, 18b, and the second cam surface or surfaces 15,17 are provided on the second cam 19. The first cam rotates to move the pins between the extended and retracted positions. The second cam 19 is moveable relative to the first cam 18a, 18b to move the pair of extended pins to the retracted position. The second cam moves lateral to, i.e. perpendicular to, a rotational axis of the first cam. A key 20 (FIG. 6B) and keyway 21 (FIG. 6A) are provided to the first and second cams to guide lateral movement of the second cam relative to the first cam.

The first and second cams are rotationally fixed together, to prevent relative rotation between the first and second cams so that the first and second cams 18a/18b, 19 rotate together. The first and second cams are rotationally fixed together by the key 20 and keyway 21. Rotation of the first and second cams together actuates the pins 6 between the retracted and extended positions to couple the hatch to the frame in a closed position by the plurality of pins engaging the plurality of pivot assemblies, and to pivotally couple the frame to the hatch by a pair of pins and corresponding pair of pivot assemblies to pivot on a hatch pivot axis at or adjacent a side of the hatch and frame, as described above.

FIG. 2C shows the actuation mechanism 7 in an open position, with a pair of pins 6 in the extended position engaged with the corresponding pair of pivot assemblies, and with all other pins in the retracted position, so that the hatch is pivotably coupled to the frame to pivot on pivot axis A4. In the open position, a pair of the cam-followers 10 are engaged with the second cam surface or surfaces 15, 17 in the radially outwards position and the other cam followers 10 are engaged with the first cam surface or surfaces 12, 14 in the radially inwards position. To move the pair of extended pins to the retracted position, the second cam 19 is moved relative to the first cam 18a, 18b from an engaged position with a pair of pins engaged with a corresponding pair of pivot assemblies as shown in FIG. 2C to a disengaged position as shown in FIG. 2D, where all pins are disengaged from the pivot assemblies.

When in the engaged position the second cam 19 rotates together with the first cam 18a, 18b as described above. To move to the disengaged position the second cam 19 is moved relative to the first cam 18a, 18b away from the hatch pivot axis A4 towards the already retracted pins, as shown in FIG. 2D. The cam second 19 moves laterally relative to the first cam 18a, 18b to move between the engaged and disengaged positions. Movement of the second cam 19 and therefore second cam surface or surfaces 15, 17 relative to the first cam 18a, 18b and therefore first cam surface or surfaces 12, 14 moves the pair of cam followers engaged with the second cam surface or surfaces 15, 17 to move the engaged pins from the extended position to the retracted position, without movement of the already retracted pins, so that all pins are retracted to uncouple and release the hatch from the frame. The hatch can then be removed from the frame as shown in FIG. 1D.

In the illustrated embodiment, the second cam 19 comprises a second track 16 to capture the cam followers in a radial direction so that the cam followers are moved between the radially outwards position and the radially inwards position by moving the second cam 19 relative to the first cam 18a, 18b between the engaged and disengaged positions. One side 15 of the track 16 acts on the cam-followers to move the cam-followers 10 to the radially inward position, and an opposite side 17 of the track moves the cam-followers to the radially outwards position. In such an embodiment the pins 6 may not be biased by a biasing element. However, where the pins are biased outwards only the cam surface 15 may be provided on the second cam, or where the pins are biased inwards, only the cam surface 17 may be provided on the second cam.

Again with reference to FIGS. 6A and 6B, the first cam 18a, 18b comprises a first part 18a and a second part 18b coupled together. The second part 18b provides the first cam with an open section 22 for receiving the second cam 19 so that the second track 16 or second cam surface 15 is aligned with the first track 13 or first cam surface 12 when the second cam 19 is in the engaged position. When the actuation mechanism is in an open position or a closed position, a pair of the cam-followers are engaged with the second track or second cam surface 15 and the first track 13 or first cam surface 12 in the radially outwards position. When the second cam 19 is moved relative to the first cam 18a, 18b to the disengaged position, the second track 16 or cam surface 15 is moved out of alignment with the first track 13 or cam surface 12 and the pair of cam followers 10 are moved by the second cam surface 15 to the radially inward position.

The first cam 18a, 18b and the second cam 19 are rotationally mounted on a spigot 26. In the illustrated embodiment the spigot extends from the hatch. The cam followers 10 are retained within the first cam or between the first cam and the second cam depending on the rotational position of the actuation mechanism. A cover 23 is provided over the first and second cams and the actuation mechanism is held together by a fastener 24 extending through the hatch 4 and first and second cams to engage the cover 23.

As described above, each pin 6 is coupled to the actuation mechanism 7 by a connecting element 11. The connecting elements 11 are received in channels or passageways 25 (FIG. 6A) in the hatch. In the illustrated embodiment, the passageways 25 are curved. The connecting elements are curved when received in the passageways so that the pins extend from the hatch at a preferred angle, e.g. 45 degrees in the illustrated embodiment. Preferably all of the pins extend at the same angle. The connecting elements are also curved so that an end of the connecting elements opposite the pin extends from the actuation mechanism 7 at a preferred angle. Preferably all of the connecting elements extend from the actuation mechanism at the same angle. For example, in the illustrated embodiment preferably the connecting elements extend radially from a rotational axis of the cam 9. In the illustrated embodiment, the curvature of the passageways and connecting elements includes an inflection point so that the pins extend at a preferred angle and the opposite ends of the connecting element extend from the actuation mechanism at a preferred angle.

In illustrated embodiment the connecting elements 11 are struts. The struts are elastically deformed to be received in the curved passageways 25 and elastically deform as the struts 11 are moved along the curved passageways to move the pins 6 between the retracted and extended positions. Alternatively, the struts may be straight. The struts and pins may be integrally formed as a unitary member. The struts and pins may have the same cross section extending from the actuation mechanism to the pivot assembly.

In a preferred embodiment, the connecting elements 11 and pins 6 are arranged on the hatch 4 to be rotationally symmetrical, so that the hatch may be coupled into the frame 2 in more than one orientation. For example, for a rectangular hatch the hatch may be inserted into the frame in one of two ways, and for a square hatch the hatch may be inserted into the frame in one of four ways.

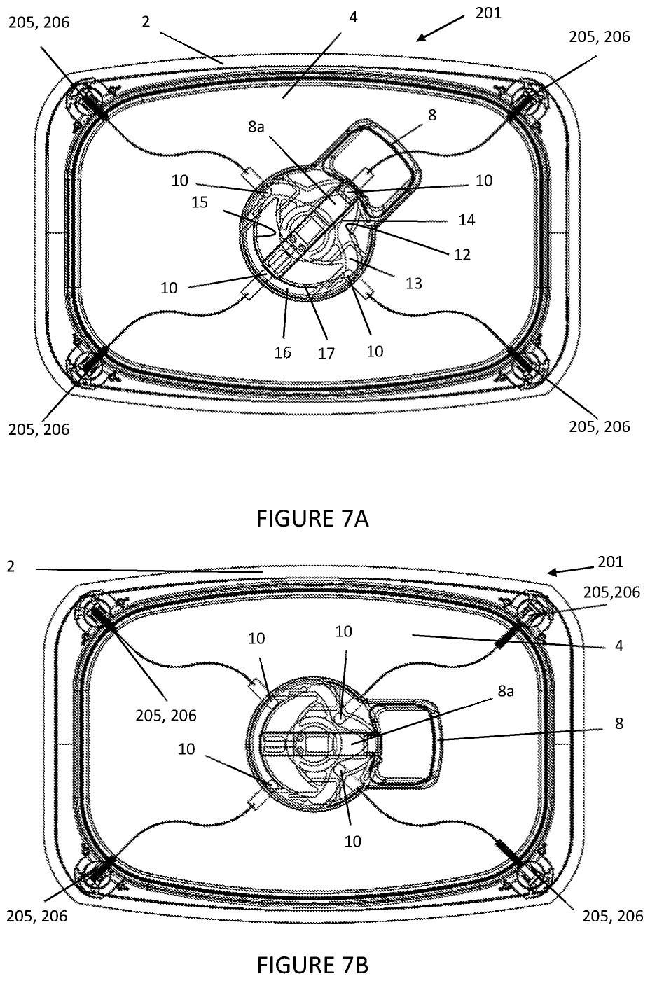

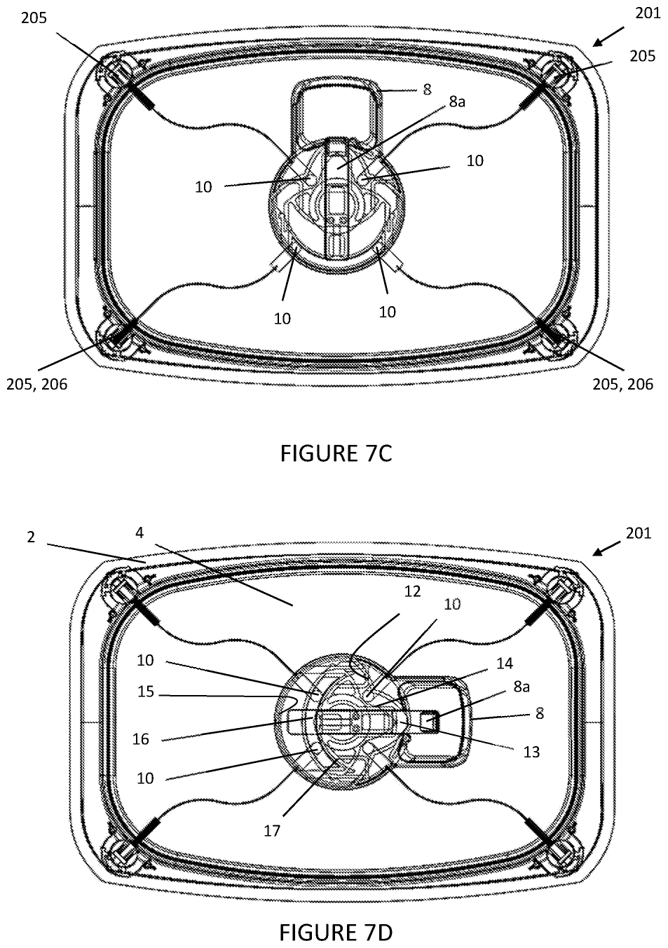

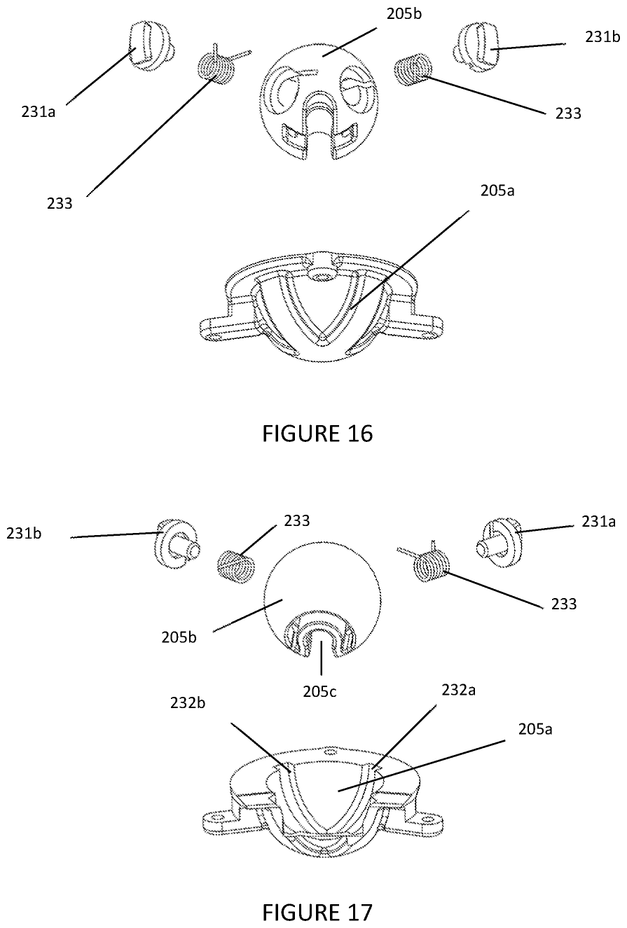

A second example embodiment for a hatch assembly 201 is described with reference to FIGS. 7A to 17. Features of the second embodiment 201 that are the same or similar to features of the above described first embodiment 1 are referenced by the same reference numerals appearing above and are not described again for brevity.

FIGS. 7A to 7D correspond with FIGS. 2A to 2D, showing the hatch 4 in a closed, open and uncoupled configurations respectively.

As described above, the handle 8 is rotationally fixed to the first and second cams 18a, 18b, 19 so that rotation of the handle 8 moves one pair of the pins 6 to the extended position and the remaining pins 6 to the retracted position. In the embodiment of FIGS. 1A to 1D, the second cam 19 is attached to or formed with the handle 8, so that lateral movement of second cam to move the pair of pins 6 from the extended position to the retracted position is achieved by lateral movement of the handle 8 relative to the first cam 18a, 18b provided for by the key and keyway 20, 21 between the first and second cams.

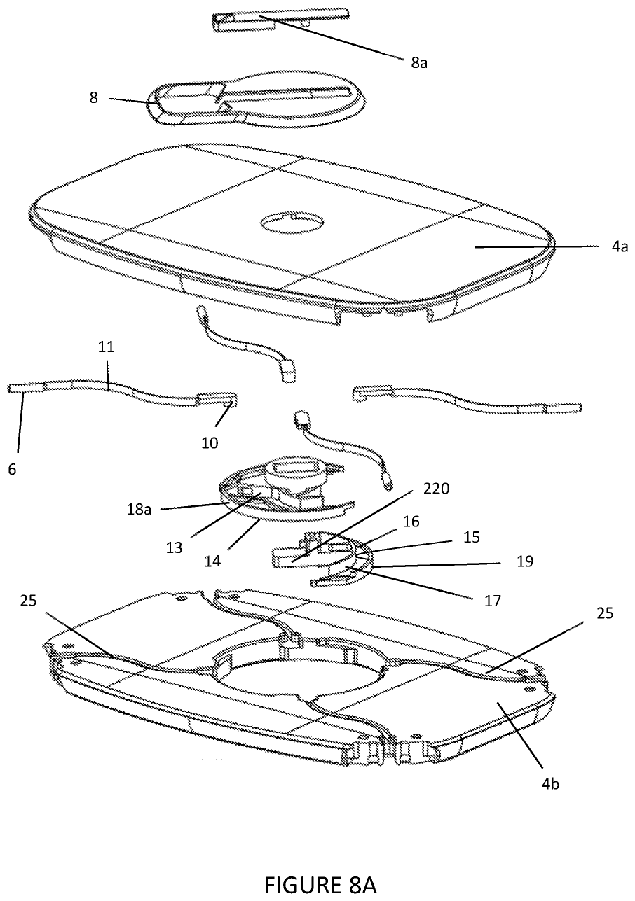

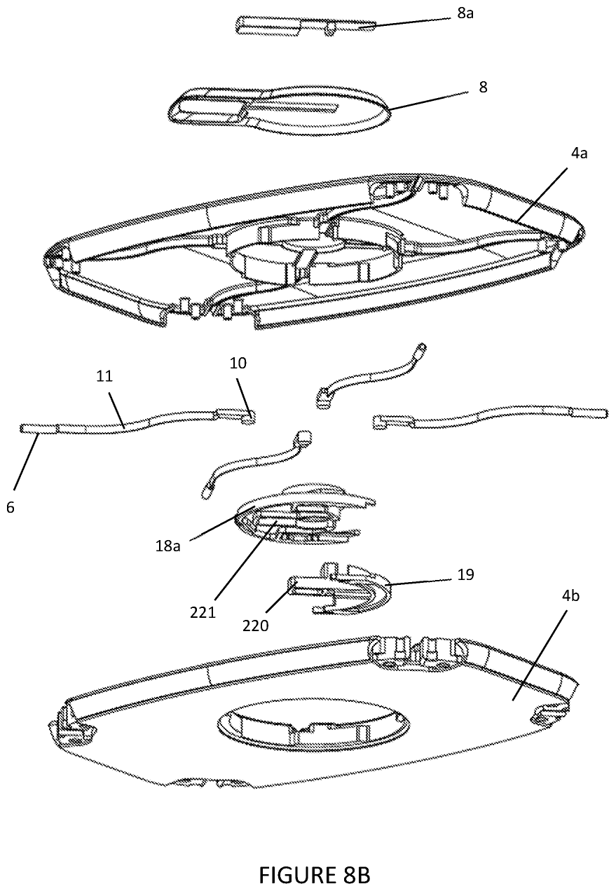

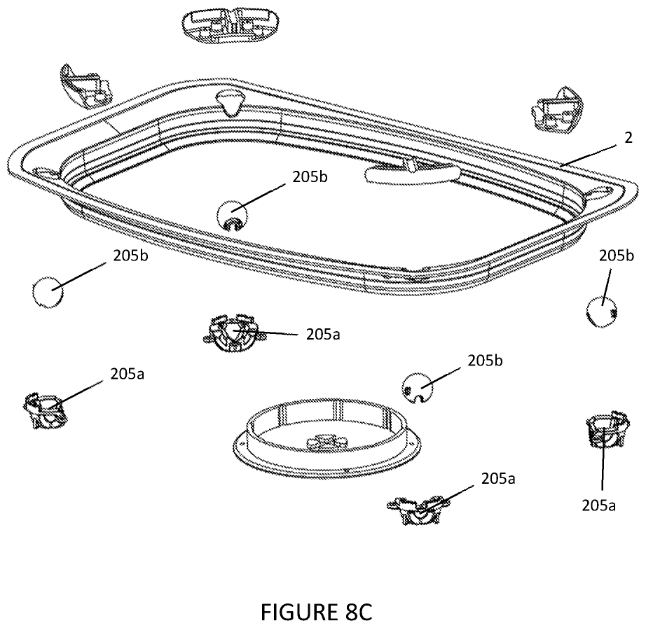

Likewise, in the second embodiment 201, the handle 8 is rotationally fixed to the first and second cams 18a, 19 so that rotation of the handle 8 moves one pair of the pins 6 to the extended position and the remaining pins 6 to the retracted position. However, in the second embodiment the handle 8 does not move laterally. With reference to FIGS. 8A to 8C, the actuation mechanism of the second embodiment 201 comprises a secondary handle 8a attached to the second cam 19. The secondary handle 8a is rotationally fixed to the second cam 19. The second cam 19 is rotationally fixed to the first cam 18a by key 220 and keyway 221. The key and keyway 220, 221 guide lateral movement of the second cam 19 and secondary handle 8a relative to the first cam 18a and handle 8. Lateral movement of second cam 19 to move the pair of pins 6 from the extended position to the retracted position (as shown in FIG. 7D) is achieved by lateral movement of the secondary handle 8a relative to the first cam 18a and handle 8 provided for by the key and keyway 220, 221. As shown in FIGS. 8A and 8B, the hatch comprises a main part 4b and an outer cover 4a. The main part may be formed from a foam material, e.g. an expanded polypropylene foam. The outer cover covers over the cam and related components of the actuation mechanism and may be formed from a plastics material. A perimeter region of the hatch is tapered or at an angle to engage a corresponding tapered or angled surface of the frame. A seal may be formed or provided to the perimeter of the hatch or the frame or both.

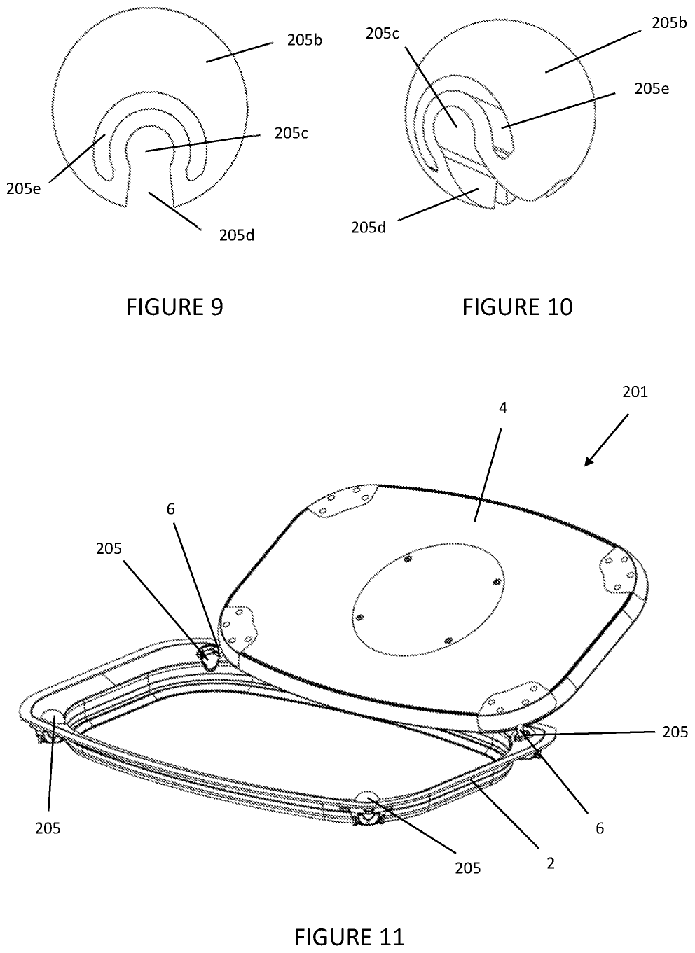

FIGS. 9 and 10 illustrate a ball of the pivot assembly of the hatch assembly 201. The ball 205b comprises an aperture 205c for receiving a said pin 6. The ball comprises a slot 205d between the aperture 205c and a side of the ball 205b, so that the aperture 205c is open to a side of the ball 205b. The aperture open to a side of the ball allows for the pin to ‘clip out’ of the ball in an event of opening the hatch 4 to beyond the fully open position (e.g. the open position shown in FIG. 11), to avoid breaking the pivot assembly, hatch or frame. To provide resiliency to the ball to allow sides of the aperture 205c to deflect to allow the pin 6 to clip out of the ball, the ball comprises a cavity 205e extending through the ball between the aperture 105c and the outside of the ball. The cavity 205e extends around the aperture 205c to either side of the slot 205d. For example, the cavity is a ‘C’ shaped cavity extending through the ball 205b. The cavity 205e extends parallel to the aperture 205c.

In the illustrated embodiment, the aperture 205c is offset from a central axis of the ball 205b. A longitudinal axis of the aperture is offset from the central axis of the ball, i.e. the longitudinal axis of the aperture 205c does not pass through a centre of the ball. The aperture 205c has a longitudinal axis parallel to a central axis of the ball. The offset aperture 205c provides for the hatch to pivot from the closed position to the open position by more than 90 degrees, to allow the hatch to open to an open position beyond 90 degrees to the frame, as shown in FIG. 11. In the illustrated embodiment the offset aperture 205c provides for the hatch to open by approximately 170 degrees from the frame.

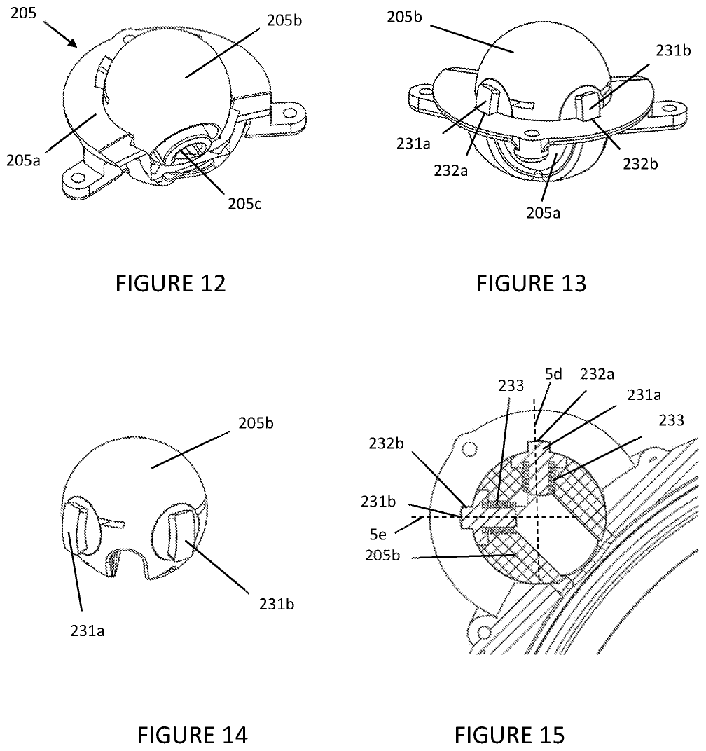

As described earlier, the pivot assembly 5, 205 may comprise a resilient element/spring to return the pivot assembly to a closed orientation when the pin 6 is retracted from the pivot assembly. With reference to FIGS. 12 to 17, in the illustrated embodiment the spring 233 is a torsion spring. The torsion spring 233 acts between the socket/first part 205a and the ball/second part 205b to return the pivot assembly to the closed orientation.

Pivot assembly 205 is configured to provide two pivot axes (5d and 5e in FIG. 15) and two springs 233, each spring associated with a respective pivot axis. Each spring is configured to bias the pivot assembly to the closed orientation about a respective pivot axis. Where the pivot assembly provides for two orthogonal pivot axes 5d, 5e as shown, the springs 233 are arranged orthogonally with respect to one another.

The pivot assembly 205 comprises a pair of keys 231a, 231b and keyways 232a, 232b to configure the ball 205b to pivot about the two pivot axes 5d, 5e, i.e. the pair of keys and keyways limit movement of the ball to pivot about the two axes. The ball selectively pivots about the first pivot axis 5d or the second pivot axis 5e to allow the hatch to open and close.

Each key 231a, 231b is coupled to the ball 205b to rotate about a respective pivot axis 5d, 5e relative to the ball 205b and is received in the associated keyway 232a, 232b in the socket 205a to prevent rotation of the key 231a, 231b relative to the socket 205a about the respective pivot axis 5d, 5e. Each spring 233 acts between the ball 205b and a respective key 231a, 231b to return the ball 205b to the closed orientation. A first key 231a rotates relative to the ball 205b about a first pivot axis 5d and is received in a corresponding first keyway 232a in the socket to prevent the first key 231a rotating about the first pivot axis 5d relative to the socket 205a and allow the ball 205b to pivot about a second pivot axis 5e. Likewise, a second key 231b rotates relative to the ball 205b about the second pivot axis 5e and is received in a corresponding second keyway 232b in the socket 205a to prevent the second key 231b rotating about the second pivot axis 5e relative to the socket 205a and allow the ball 205b to pivot about the first pivot axis 5d. Each spring 233 biases the rotation of the respective key 231a, 231b relative to the ball to bias the ball relative to the socket to the closed orientation. Where the pivot axes are orthogonal, the first key and keyway are orthogonal to the second key and keyway. For example, the first key and keyway extend on a first plane and the second key and keyway extend on a second plane orthogonal to the first plane, the first and second planes extending through a centre of the ball on which the ball pivots.

### Variations

In the illustrated embodiments the pivot assemblies are mounted to the frame and with the engagement mechanism mounted to the hatch. However, in some embodiments the pivot assemblies may be mounted to the hatch, with the engagement mechanism mounted to the frame. In such an embodiment the pivot assembly first part is fixed to or formed with the hatch and the second part is coupled to the first part and adapted to pivot relative to the first part. In such an embodiment, the pins of the engagement mechanism are extended inwards from the frame to engage the pivot assemblies and are retracted back into the frame to disengage from the pivot assemblies. In such an embodiment the longitudinal axes of the pins converge to a centreline of the hatch to ensure the hatch remains coupled to the frame by a pair of pivot assemblies when pivoted open.

Alternative actuation mechanisms are possible. For example, alternative connecting elements may be provided, for example the struts in the above described actuation mechanism may be replaced with cables or hydraulic or pneumatic systems, or the actuation mechanism may comprise an electrical system to drive the pins between the retracted and extended positions via electrical actuators such as solenoids. Such arrangements may be employed when the pivot assemblies are mounted to the hatch and the pins and actuation mechanism are mounted to the frame 2 or other member attached to the frame. For example, cables may be routed in passageways extending around the frame between the actuation mechanism and the pins. In such an embodiment, each pin may be biased by a spring to engage the respective pivot assembly on the hatch, so that the cables operate in tension to retract the pins.

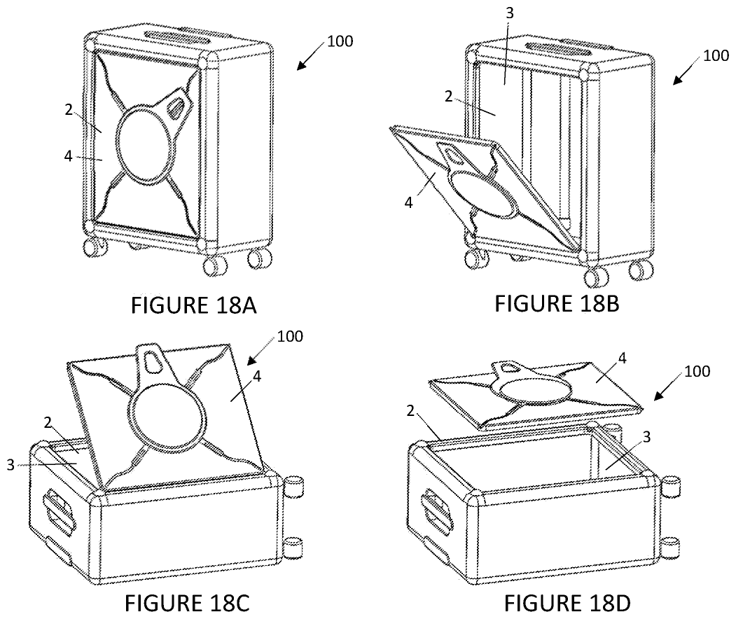

A hatch assembly according to the present invention may be utilised whenever a hatchway is required to open and close access to a space, for example a wall or ceiling cavity of a building, such as a door or window. FIGS. 18A to 18D show the hatch assembly 1 of FIGS. 1A to 1D incorporated into an item of luggage 100 (a suitcase). The frame 2 of the hatch assembly 1 forms part of or is built into a case of the item of luggage. FIGS. 19A to 19D illustrate a hatch assembly in the form of a circular manhole cover assembly 101. The circular hatch assembly 101 comprises a circular hatch frame 102 with frame opening 103, a circular hatch 104, and three pivot assemblies 5. The pivot assemblies 5 are equi-spaced around the hatch 104 and frame 102. The hatch 104 may be pivoted open on any one of three hatch pivot axes A1, A2, A3 identified in FIG. 19A, each hatch pivot axis provided by a pair of adjacent pivot assemblies 5. The manhole assembly 101 may have an actuation mechanism that functions as described above but for providing the three hatch pivot axes, for coupling the hatch to the frame in the closed position, and for the hatch to be uncoupled and removed from the manhole. The actuation mechanism may be enclosed within outer covers of the manhole cover or below a top cover to be hidden from view when the manhole cover is closed. The actuation mechanism may be accessed and actuated by a key 27 inserted through a keyway 28 in a top cover of the manhole cover 104 to operate the actuation mechanism.

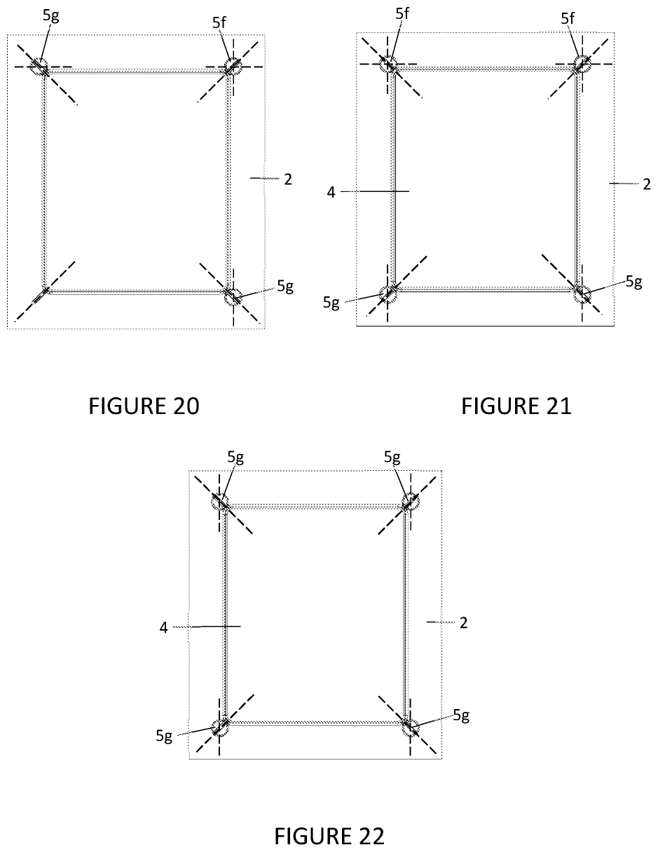

The example embodiment of FIGS. 1A to 1D comprises a pair of pivot assemblies associated with each side of the hatch, with each pivot assembly associated with a corner of the hatch and comprising two pivot axes, such that each pivot assembly is shared between adjacent hatch pivot axes and sides of the hatch. The number of pivot assemblies is equal to the number of sides of the hatch, and the number of adjacent pairs of pivot assemblies is equal to the number of sides of the hatch. However, in some embodiments, the number of pivot assemblies may be more than or less than the number of sides or corners of a hatch. For example, a four-sided hatch assembly may comprise a pivot assembly associated with three corners of the hatch, as shown in FIG. 20. The three pivot assemblies 5f, 5g provide two pairs of pivot assemblies each providing a hatch pivot axis. The pivot assembly 5f located between the other two pivot assemblies 5g may have two pivot axes to be shared by two adjacent hatch pivot axes. The other two pivot assemblies 5g may have two pivot axes, or a single pivot axis only, aligned with one of the pivot axes of the pivot assembly 5f with two pivot axes. The engagement mechanism may include four pins 6, with three pins releasably engaging the three pivot assemblies 5f, 5g and a fourth pin engaging a corner of the frame 2 without a pivot assembly. Such an arrangement provides a four-sided hatch that is selectively configurable to pivot to an open position on two adjacent hatch pivot axes at or adjacent two adjacent sides of the hatch.

In another example embodiment, a hatch assembly may comprise two adjacent pivot assemblies each associated with a corner of the hatch and each having two pivot axes, and with the other pivot assemblies each having a single pivot axis only aligned with one of the pivot axes of the adjacent pivot assembly with two pivot axes. For example, with reference to FIG. 21, a four-sided hatch assembly may have two adjacent pivot assemblies 5f each associated with a corner of the hatch and with two pivot axes, and two adjacent pivot assemblies 5g at or adjacent an opposite side or opposed corners of the hatch each with a single pivot axis. Such an arrangement provides a hatch that is selectively configurable to pivot to an open position on three adjacent hatch pivot axes at or adjacent three adjacent sides of the hatch.

In yet another example embodiment, a hatch assembly may comprise a pair of pivot assemblies associated with each of two or more sides of the hatch, with each pivot assembly having a single pivot axis only. For example, as shown in FIG. 21, a four-sided hatch assembly may have two adjacent pivot assemblies 5g each with a single pivot axis at one side of the hatch and two adjacent pivot assemblies each with a single pivot axis at an opposite side of the hatch. Such an arrangement provides a hatch that is selectively configurable to pivot to an open position on two opposed sides of the hatch.

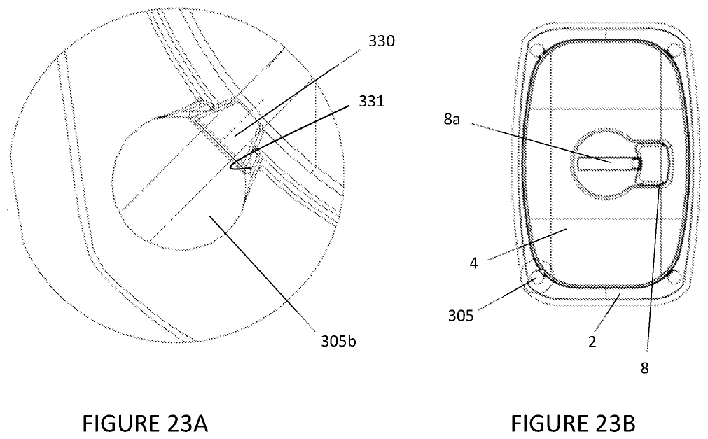

With reference to FIGS. 23A and 23B, in some embodiment, the hatch 4 may include a key member 330 to engage a corresponding keyway 331 of a corresponding pivot assembly 305. The hatch key 330 is received in the pivot assembly keyway 331 in the ball 305b of the corresponding pivot assembly 305 when the hatch 4 is coupled to the corresponding pivot assembly 305. It is envisaged that alternatively the ball 305b may comprise the key 330 and the hatch 4 the corresponding keyway 331. The key 330 and keyway 331 are configured so that the key engages and disengages the keyway (when the pin 6 at the corresponding pivot assembly 305 is retracted) by pivoting of the hatch 4 about the hatch pivot axis at an opposite side of the hatch 4 to the pivot assembly 305. The key and keyway are shaped to resist or restrict the hatch 4 from pulling away from the (pair of) connected pivot assemblies 305 when the hatch 4 is opened, e.g. prevents or restricts the hatch pulling away from the pivot assembly along the longitudinal axis of the pin 6 coupled with the pivot assembly. By example, in the illustrated example the key 330 and keyway 331 are dovetail shaped. The key and keyway may further secure the hatch 4 to the pivot assembly 305 in addition to the angled/converging pins, to prevent or resist the hatch 4 pulling away from the connected pivot assemblies 305 when opened.

In the above described embodiments the engagement mechanism includes pairs of pins to engage corresponding pairs of pivot assemblies to selectively couple the hatch to the frame in closed and multiple pivotable configurations. The pins are oriented so that the longitudinal axes of the pins in each pair of pins converge, so that the hatch remains coupled to the frame when the hatch is pivoted open.

A hatch assembly according to the present invention provides a simple arrangement that conveniently provides for multiple hatch pivot axes, and in a preferred embodiment allows for the hatch to be completely removed from the frame. The hatch is coupled to the frame by pins engaging the pivot assemblies only. With the pairs of pins arranged with converging longitudinal pin axes, selective coupling of the hatch to the frame is simplified. Furthermore, the invention provides for easy configurability of the hatch. The actuation mechanism provides actuation of the engagement mechanism to couple the hatch to the frame in the closed and multiple pivoting open configurations, and in a preferred embodiment a further release configuration in which the hatch can be removed from the frame.

Where in the foregoing description reference has been made to integers or components having known equivalents thereof, those integers are herein incorporated as if individually set forth.

It should be noted that various changes and modifications to the presently preferred embodiments described herein will be apparent to those skilled in the art. Such changes and modifications may be made without departing from the spirit and scope of the invention and without diminishing its attendant advantages. It is therefore intended that such changes and modifications be included within the present invention

1. A hatch assembly comprising:
a frame presenting a frame opening;
a hatch for opening and closing the frame opening;
a plurality of pivot assemblies, wherein at least two pairs of the pivot assemblies each provide a hatch pivot axis at or adjacent a side of the hatch,
an engagement mechanism configured to releasably engage the pivot assemblies to couple the hatch to the frame;
wherein the engagement mechanism comprises a plurality of pins, each pin movable between an extended position to engage a said pivot assembly and a retracted position to disengage from the pivot assembly; and
an actuation mechanism configured to move the pins between the extended and retracted positions, to selectively couple the hatch to the frame by:
(i) all of the pivot assemblies engaged by all of the pins to couple the hatch to the frame in a closed position, and
(ii) any said pair of pivot assemblies engaged by a corresponding pair of the pins to selectively pivotally-couple the hatch to the frame to pivot on the hatch pivot axis at or adjacent any of at least two sides of the hatch, and
wherein the pins are oriented so that longitudinal axes of the pins in each pair of pins converge enabling the hatch to remain coupled to the frame when the hatch is pivoted between the closed position and an open position.

2. The assembly as claimed in claim 1, wherein the actuation mechanism is configured to move all of the pins to the retracted position to uncouple the hatch from the frame to optionally remove the hatch from the frame.

3. The assembly as claimed in claim 1, wherein pairs of the pivot assemblies each provide a hatch pivot axis at or adjacent a side of the hatch, so that the plurality of pivot assemblies provides a hatch pivot axis at or adjacent each side of the frame,
the actuation mechanism configured to selectively couple the hatch to the frame by any said pair of pivot assemblies engaged by a corresponding pair of the pins to selectively pivotally-couple the hatch to the frame to pivot on the hatch pivot axis at or adjacent any side of the hatch.

4. The assembly as claimed in claim 1, wherein one or more pivot assemblies comprises at least two pivot axes, wherein the one or more pivot assemblies is shared between two adjacent hatch pivot axes for two adjacent sides of the hatch and frame.

5. The assembly as claimed in claim 1, wherein each pivot assembly comprises at least two pivot axes, wherein each pivot assembly is shared between two adjacent hatch pivot axes for two adjacent sides of the hatch and frame.

6. The assembly as claimed in claim 1, wherein each pivot assembly is associated with a corner of the hatch and frame.

7. The assembly as claimed in claim 1, wherein pairs of adjacent pivot assemblies each provide a hatch pivot axis, and wherein the actuation mechanism is configured to selectively pivotally-couple the hatch to the frame by any said pair of adjacent pivot assemblies engaged by a corresponding pair of adjacent pins.

8. The assembly as claimed in claim 1, wherein the number of hatch pivot axes is equal to the number of pivot assemblies.

9-11. (canceled)

12. The assembly as claimed in claim 1, wherein the actuation mechanism provides a plurality of closed positions to selectively couple the hatch to the frame in the closed position.

13. The assembly as claimed in claim 12, wherein in each closed position a handle of the actuation mechanism is aligned towards a corner region of the hatch.

14. The assembly as claimed in claim 1, wherein the actuation mechanism provides a plurality of open positions, in each open position the hatch pivotally coupled to the frame to pivot on a said hatch pivot axis.

15. The assembly as claimed in claim 14, wherein in each open position a handle of the actuation mechanism is oriented away from the respective hatch pivot axis.

16. The assembly as claimed in claim 1, wherein the actuation mechanism comprises a cam to move the pins between the extended and retracted positions,
wherein each pin is coupled to the cam by a cam follower and a connecting element extending between the cam follower and the pin, wherein the cam comprises at least one cam surface to act on and thereby move the cam-followers between a radially inward position and a radially outward position to move the pins between the retracted and extended positions.

17. (canceled)

18. The assembly as claimed in claim 16, wherein the cam captures the cam followers in a radial direction so that the cam followers are moved between the radially inwards position and the radially outwards position by rotation of the cam.

19. The assembly as claimed in claim 16, wherein the cam comprises:
a first cam comprising at least one first cam surface for moving the pins between the retracted and extended positions to couple the hatch to the frame in the closed position and pivotally couple the hatch to the frame by a pair of pivot assemblies, and
a second cam comprising at least one second cam surface moveable relative to the at least one first cam surface to move the pair of pins engaged with a corresponding pair of pivot assemblies from the extend position to the retracted position to uncouple the hatch from the frame to optionally remove the hatch from the frame.

20. The assembly as claimed in claim 19, wherein the second cam is moveable relative to the first cam to move the pair of pins engaged with a corresponding pair of pivot assemblies from the extended position to the retracted position.

21. The assembly as claimed in claim 19 wherein the at least one first cam surface and the at least one second cam surface are aligned to move the pins between the retracted and extended positions to couple the hatch to the frame in the closed position and pivotally couple the hatch to the frame by a pair of pivot assemblies, and
wherein the second cam is moved relative to the first cam to move the at least one second cam surface out of alignment with the at least one first cam surface to move the pair of pins engaged with a corresponding pair of pivot assemblies from the extend position to the retracted position to uncouple the hatch from the frame to optionally remove the hatch from the frame

22-25. (canceled)

26. The assembly as claimed in claim 1, wherein each pin is coupled to the actuation mechanism by a connecting element received in a channel or passageway.

27. The assembly as claimed in claim 26, wherein the channels or passageways are curved so that the connecting elements are curved when received in the channels or passageways so that the pins extend at a preferred angle between the longitudinal axis of each pin and the corresponding hatch pivot axis.

28-34. (canceled)

35. The assembly as claimed in claim 1, wherein each pivot assembly comprises a spring to return the pivot assembly to a closed orientation when the pin is retracted from the pivot assembly.

36-38. (canceled)
